(19) United States
(12) Patent Application Publication
(10) Pub. No.: US 2010/0321901 A1
(43) Pub. Date: Dec. 23, 2010

(54) OPTICAL ELEMENT, ELECTRONIC MODULE AND METHOD OF PRODUCING ELECTRONIC MODULE

(76) Inventors: Shuji Murakami, Tokyo (JP); Mika Honda, Tokyo (JP); Takashi Washizu, Tokyo (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/525,996

(22) PCT Filed: Jan. 18, 2008
(86) PCT No.: PCT/JP2008/050594

§ 371 Date: Aug. 5, 2009

(30) Foreign Application Priority Data
Feb. 9, 2007 (JP) 2007 030434

(51) Int. Cl. H05K 7/00; G02F 1/361; H05K 3/30

(52) U.S. Cl. 361/748; 252/582; 29/846

(57) ABSTRACT

Disclosed are: an optical element which is reduced in the changes in transmittance which may be caused by a reflow processing; an electronic module; and a method of producing an electronic module. The optical element comprises an optical material which comprises a curable resin material comprising a curable resin and a curing agent and at least one additive, wherein the light transmittance of the optical material at a wavelength of 400 nm is lower by 1 to 10% than that of the curable resin material without the additive at a wavelength of 400 nm.

### FIELD OF THE INVENTION

The present invention relates to an optical element, specifically to an optical element which can be subjected to a reflow treatment, an electronic module, and a method of producing the electronic module.

### BACKGROUND OF THE INVENTION

As an optical element used for such as an imaging optical system, for example, a silver halide camera and a digital camera, or an optical system for optical pickup devices, glass optical elements and plastic optical elements have been conventionally known. Plastic optical elements have been preferably used because of its excellent moldability, and low cost. Generally, thermoplastic resins, such as polyolefine, have been used as an optical material for an imaging optical system or an optical pickup system.

In contrast, a technology has been developed to manufacture electronic modules at low cost via a technique wherein in cases in which IC (Integrated Circuits) chips and other electronic parts are mounted on a circuit board, conductive paste (for example, solder) is previously subjected to coating (potting) on predetermined locations of a circuit board, and then the circuit board is subjected to reflow treatment (heating treatment) in a state where electronic parts are placed at the locations to mount the electronic parts on the circuit board by melting the conductive paste (for example, Patent Document 1).

Over recent years, improvements of productivity in production systems of optical modules have been desired, by mounting an optical element, in addition to electronic parts, on a circuit board, followed by reflow treatment, as described above, to fabricate an all-in-one optical module including the optical element.

Also for the optical module manufactured by the production system employing the abovementioned solder reflow process, it is natural that the use a plastic optical element, which can be manufactured at low cost, is desired, rather than a high cost glass optical element. However, when an optical element made from a commonly employed thermoplastic resin is used, a problem arises is that the optical element is deformed while heated in the reflow treatment, resulting in failure to obtain the optical function as an optical element. Among plastic materials, curable resins have been known to be more thermally resistant compared to thermoplastic resins (for example, refer to curable resins disclosed in Patent Document 2).

According to paragraphs [0008] and [0033]-[0035] of Patent Documents 2, it has been disclosed that the curable resins are resistant against a thermal treatment to some extent, however, it was found that, when a curable resin was actually subjected to a reflow treatment, a change of transmittance of the optical element before and after the reflow treatment was observed.

If a change occurs in transmittance before and after a reflow treatment, the optical property of the optical element before the reflow treatment will differ from the optical property after the reflow treatment, and when high accuracy is desired for an optical element, for example, for an imaging device or for an optical pick-up device, it may have been a problem.

Patent Document 1 Japanese Patent Application Publication Open to Public Inspection (hereafter referred to as JP-A) No. 2001-24320

Patent Document 2 JP-A No. 2006-335894

### DISCLOSURE OF THE INVENTION

### Problem to be Solved by the Invention

Therefore, a main object of the present invention is to provide an optical element in which the change of transmittance before and after a reflow treatment is minimized, whereby the optical property of an optical element before a reflow treatment is maintained even after the reflow treatment. Another object of the present invention is to provide an electronic module mounting such an optical element and a method of producing the optical module.

### Means to Solve the Problem

A first embodiment of the present invention is an optical element comprising an optical material comprising a curable resin material and at least one additive, the curable resin material comprising a curable resin and a curing agent, wherein a light transmittance at a wavelength of 400 nm of the optical material is lower by 1-10% than a light transmittance at a wavelength of 400 nm of the curable resin material before addition of the at least one additive.

“The light transmittance at a wavelength of 400 nm” refers to a value obtained by using a 3 mm thickness plate. In the case of a lens having a spherical surface, the transmittance of the lens is measured and then it can be converted to the value for a 3 mm thickness plate.

As the results of intensive study by the present inventors, it was found that, in the case when an optical element having a curable resin material as a main component is subjected to a heat treatment such as a reflow treatment, the change in the light transmittance due to the heat treatment can be reduced by preliminarily adding an additive which lowers the light transmittance of a curable resin material. By employing such a constitution, the difference between the light transmittance of the optical element when it is practically used, for example, as an imaging apparatus, and the light transmittance of the optical element when it is molded, can be reduced.

In the first embodiment, it is preferable that the additive is a phosphorus-containing stabilizer.

In the first embodiment, it is preferable that the curable resin is a silicone resin, an epoxy resin, a resin having an adamantane moiety or a resin containing an acrylate.

A second embodiment of the present invention is an electronic module produced by the steps of: mounting the optical element of the first embodiment, and at least an electronic circuit and a solder material, on an electronic circuit board; and heating the electronic circuit board to a temperature at which the solder material is melted.

A third embodiment of the present invention is a method of producing an electronic module comprising the steps of: mounting the optical element of the first embodiment, and at least an electronic circuit and a solder material, on an electronic circuit board; and heating the electronic circuit board to a temperature at which the solder material is melted.

### EFFECTS OF THE INVENTION

According to the abovementioned embodiments of the present invention, an optical element in which the change of transmittance before and after a reflow treatment is minimized, whereby the optical property of the optical element before a reflow treatment is maintained even after the reflow treatment can be provided, as well as an electronic module and a method of producing an electronic module can be provided (refer to the following embodiment).

### BRIEF DESCRIPTION OF THE DRAWING

FIG. 1 is a cross-sectional view showing the schematic constitution of the optical element according to a preferable embodiment of the present invention.

### EXPLANATION OF A NUMERAL

1 Optical element

### BEST MODE FOR CARRYING OUT THE INVENTION

Preferable embodiments of the present invention will be explained below with referring to the drawing.

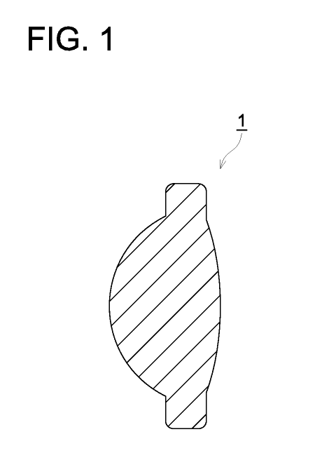

As shown in FIG. 1, Optical element 1 functions as a convex lens which is usable in a reflow treatment in which an electric circuit and electronic parts are soldered. Optical element 1 is made mainly from a curable resin in which the change in transmittance due to reflow treatment is minimized by adding a predetermined additive.

Measurement of the transmittance change of the optical element of the present invention is carried out by measuring the transmittance at a wavelength of 400 nm. More specifically, a 3 mm thick molding is prepared and the transmittance thereof is measured by using U4100 produced by Hitachi Ltd. When the transmittance of the optical element before and after heat treatment is compared, the optical element is placed in a 260° C. furnace and then took out after three minutes. The transmittances before and after the heat treatment are determine according to the abovementioned method. When the optical element is a lens having a refracting power, the transmittance is measured by placing two lens together, while both emitting surfaces face each other, to produce parallel light, whereby the measure value can be converted to a transmittance of a mold of a thickness of 3 mm.

First, the type of (1) curable resins and (2) additives will be explained and, subsequently, (3) the type of hardening agents which can be added, and (4) the method of producing an optical element, will be explained.

### (1) Curable Resin

A curable resin means a resin which can be cured by irradiation of ultra-violet rays or electron beams, or a heat-treatment, whereby a cured transparent resin composition is formed. When one of the following additives usable in the present invention is added to the cured resin according to the present invention, the light transmittance at a wavelength of 400 nm of the optical material added with the additive becomes lower by 1-10% compared to the transmittance before addition of the additive. Examples of such a curable resin include the following resins.

### (1.1) Epoxy Resin

Usable are, for example, a cycloaliphatic epoxy resin such as 3,4-epoxycyclohexylmethyl-3′-4′-cyclohexylcarboxylate, (refer to WO2004/031257), an epoxy resin having a spiro ring and a linear aliphatic epoxy resin.

### (1.2) Resin Having an Adamantane Moiety

Usable are curable resins having an adamantane skeleton with no aromatic ring (refer to JP-A 2001-322950) such as 2-alkyl-2-adamantyl (meth)acrylates (refer to JP-A 2002-193883), 3,3′-dialkoxycarbonyl-1,1′-biadamantanes (refer to JP-A No. 2001-253835), 1,1′-biadamantane compounds (refer to U.S. Pat. No. 3,342,880), tetraadamantanes (refer to JP-A 2006-169177), 2-alkyl-2-hydroxyadamantanes, 2-alkyleneadamantanes, di-tert-butyl-1,3-adamantanedicarboxylate; bis(hydroxyphenyl)adamantanes; and bis(glycidyloxyphenyl)adamantanes (refer to JP-A Nos. 11-35522 and 10-130371).

### (1.3) Resin Containing Allyl Ester Compound

Preferably used, for example, are bromine-containing (meth)allyl esters having no aromatic ring (refer to JP-A 2003-66201), allyl(meth)acrylates (refer to JP-A 5-286896), allyl ester resins (refer to JP-A Nos. 5-286896 and 2003-66201), copolymers of an acrylic acid ester and an epoxy group-containing unsaturated compound (refer to JP-A 2003-128725), acrylate compounds (refer to JP-A 2003-147072), and acrylic ester compounds (refer to JP-A 2005-2064).

### (1.4) Resin Containing Acrylate

Curable resins prepared from monomers of methacrylic ester or acrylic ester can be preferably used.

Examples include: methyl methacrylate, ethyl methacrylate, propyl methacrylate, n-butyl methacrylate, butyl methacrylate, t-butyl methacrylate, dodecyl methacrylate, octadecyl methacrylate, cyclohexyl methacrylate, methylcyclohexyl methacrylate, isobornyl methacrylate, tricyclodecyl methacrylate, adamantyl methacrylate, 2-hydroxyethyl methacrylate, 2-hydroxypropyl methacrylate, phenyl methacrylate, benzyl methacrylate, tetrahydrofurfuryl methacrylate, glycidyl methacrylate, cyclohexyl methacrylate, isobonyl methacrylate, methyl acrylate, ethyl acrylate, propyl acrylate, n-butyl acrylate, i-butyl acrylate, 2-ethylhexyl acrylate, diethyleneglycol ethoxyrate acrylate, n-stearyl acrylate, lauryl acrylate, dodecyl acrylate and tetrahydrofurfuryl acrylate.

### (2) Additives

The additive according to the present invention is not specifically limited as far as the additive lowers the light transmittance by 1-10%, however, it is preferable to use at least one selected from phosphorus-containing stabilizer. Phosphorus-containing stabilizers are not specifically limited as far as it is commonly used in the resin industry, of which examples include: monophosphites such as triphenyl phosphite, diphenylisodecyl phosphite, phenyldiisodecyl phosphite, tris(nonylphenyl)phosphite, tris(dinonylphenyl)phosphite, tris(2,4-di-t-butylphenyl)phosphite, 10-(3,5-di-t-butyl-4-hydroxybenzyl)-9 and 10-dihydro-9-oxa-10-phosphaphenanthrene-10-oxide; and diphosphites such as 4,4′-butylidene-bis(3-methyl-6-t-butylphenyl-di-tridecyl phosphite) and 4,4′-isopropylidene-bis(phenyl-di-alkyl(C12-C15) phosphite). Of these, monophosphite compounds are preferable and specifically preferable are, for example, tris(nonylphenyl)phosphite, tris(dinonylphenyl)phosphate and tris(2,4-di-t-butylphenyl)phosphite.

### (3) Curing Agent

A curing agent is used to constitute a curable resin material, and the curing agent is not specifically limited. In the present invention, the curing agent is not included in the additive when comparing the transmittance of a curable resin material and the transmittance of an optical material added with an additive. As a curing agent, an acid anhydride curing agent and a phenol curing agent, for example, can be preferably used.

Specific examples of the acid anhydride curing agent include: phthalic anhydride, maleic anhydride, trimellitic anhydride, pyromellitic anhydride, hexahydrophthalic anhydride, 3-methyl-hexahydrophthalic anhydride, 4-methyl-hexahydrophthalic anhydride, an admixture of 3-methyl-hexahydrophthalic anhydride and 4-methyl-hexahydrophthalic anhydride, tetrahydrophthalic anhydride, nadic anhydride and methylnadic anhydride. A curing accelerator is also contained, if necessary. The hardening accelerator is not specifically limited, as long as the hardening accelerator exhibits excellent hardenability, causes no coloration, and keeps the transparency of a thermosetting resin. Examples of such a hardening accelerator include: imidazoles such as 2-ethyl-4-methylimidazole (2E4MZ), a tertiary amine, a quaternary ammonium salt, bicyclic amidines such as diazabicycloundecene and derivatives thereof, phosphine and a phosphonium salt. These may be used singly or in combination of at least two kinds.

Further, as a curing agent, an organic peroxide may be employed if appropreate. As an organic peroxide, preferable products include: PERHEXA HC, PERHEXA V, PERHEXA 25B, PERBUTYL P, PERHEXYL D, PEROYL TCP, PEROYL L, PEROCTA O, PERBUTYL O, PERBUTYL L, PERBUTYL 355, PERHEXYL I and PERBUTYL E, all of which are produced by NOF Corp., however, the curing agent is not limited thereto.

### (4) Method of Producing Optical Element

Each of the abovementioned material is suitably prepared and the prepared product (resin composition) is molded.

In the molding process, a resin composite can be molded in prescribed shape by curing the curable resin in the resin composition obtained by the abovementioned preparation process with light or heat, and the optical element according to the present invention can be manufactured.

Specifically, when the curable resin is an ultra-violet ray curable resin or an electron beam curable resin, the resin composition is charged into a transparent molding die of the prescribed shape or applied onto a substrate, and then cured via irradiation of ultraviolet-rays or electron beams. When the curable resin is a thermosetting resin, the resin composition is molded via compression molding, transfer molding or injection molding, and then cured.

When a sheet-like or film-like optical element (for example, a polarizer) is produced, a photo-curable resin cured with actinic energy rays, such as visible rays, ultra-violet rays and electron beams, are preferably employed. In this case, the resin composition is charged into a transparent molding die of a prescribed shape or applied onto a substrate, followed by curing the photo curable resin contained in the resin composition to form the resin composition into a prescribed shape.

On the other hand, when an optical element (for example, an objective lens) which has a spherical surface or an aspheric surface and has a minute structure on the optical surface is manufactured, a thermosetting resin which is cured by heat is preferably employed.

### EXAMPLES

### (1) Production of Samples

### (1.1) Production of Sample 1

A silicone resin, Liquid A of LPS-L-500 produced by Shin-Etsu Chemical Co., Ltd., which was designated as Resin A, was cured at a thickness of 1 mm at 150° C. for 1 hour and further cured at 150° C. for 2 hours to obtain Sample 1.

### (1.2) Production of Sample 2

Sample 2 was produced in the same manner as Sample 1 except that 0.3% of tris(2,4-di-t-butylphenyl)phosphite was added as Additive A to Resin A of Sample 1.

### (1.3) Production of Sample 3

Sample 3 was produced in the same manner as Sample 1 except that, instead of Additive A used in the production method of Sample 2, the same amount of following Additive B was added.

### Additive B: Tris(dinonylphenyl)phosphite

### (1.4) Production of Sample 4

Sample 4 was produced in the same manner as Sample 1 except that, instead of Additive A used in the production method of Sample 2, the same amount of following Additive C was added.

### Additive C: Octadecyl-3-(3,5-di-t-butyl-4-hydroxyphenyl)propionate

### (1.5) Production of Sample 5

Sample 5 was produced in the same manner as Sample 1 except that, instead of Additive A used in the production method of Sample 2, the same amount of following Additive D was added.

### Additive D: Distearyl-3,3-thiodipropionate

### (1.6) Production of Sample 6

Sample 6 was produced in the same manner as Sample 1 except that, instead of Additive A used in the production method of Sample 2, the same amount of following Additive E was added.

### Additive E: bis(2,2,6,6-tetramethyl-4-piperidyl) succinate

### (1.7) Production of Sample 7

Into an epoxy resin containing an aromatic group, the same amount of phthalic anhydride was added to obtain Resin B. Resin B was cured at a thickness of 1 mm at 150° C. for 1 hour and further cured at 150° C. for 2 hours to obtain Sample 7.

### (1.8) Production of Sample 8

Sample 8 was produced in the same manner as Sample 7 except that 0.3% of Additive A was added to Resin B of Sample 7.

### (1.9) Production of Sample 9

Sample 9 was produced in the same manner as Sample 1 except that Resin C was used instead of Resin A, wherein Resin C was prepared by using 2-alkyl-2-adamantyl(meth)acrylate prepared according to the method disclosed in JP-A No. 2002-193883 and 1% of PERBUTYL 0 produced by NOF Corp. as a curing agent.

### (1.10) Production of Sample 10

Sample 10 was produced in the same manner as Sample 9 except that 0.3% of Additive A was added to Resin C of Sample 9.

### (1.11) Production of Sample 11

Sample 11 was produced in the same manner as Sample 1 except Resin D was used instead of Resin A, wherein Resin D was prepared by using an allyl ester resin BA901 produced by Showa Denko K.K. and 1% of PERBUTYL O produced by NOF Corp. as a curing agent.

### (1.12) Production of Sample 12

Sample 12 was produced in the same manner as Sample 11 except that 0.3% of Additive A was added to Resin D of Sample 11.

### (2) Evaluation of Each Sample

### Measurement of Light Transmittance of Each Sample

The light transmittance of each of Samples 1-12 was measured using a transmittance meter (U-4100 produced by Hitachi Ltd.) at a wavelength of 400 nm. The results were shown in following Table 1. Specifically, for Samples 2-6, 8, 10 and 12, in each of which an additive was added to the curable resin, the light transmittances at a wavelength of 400 nm were varied before and after the addition of the additive, and the transmittance changes were calculated (Transmittance change=(Transmittance after the addition−Transmittance before the addition)). The results of the calculations were shown in following Table 1.

After that, each of Samples 1-12 was subjected to a thermal treatment (a heat treatment) at 260° C. for 3 minutes, and the light transmittance of each of Samples 1-12 at a wavelength of 400 nm was measured after the heat treatment using a transmittance meter (U-4100 produced by Hitachi Ltd.). Then, the change in transmittance before the heat treatment (as for the sample added with an additive, the transmittance after addition of the additive was measured), and the transmittance after the heat treatment was calculated (Change=(transmittance before the heat treatment−transmittance after the heat treatment)). The results of the calculation were shown in following Table 1.

In Table 1, the criteria of “A” and “B” in the item of “Transmittance change (%) due to heat treatment” were as follows.

A: 10% or less

B: 11% or more

TABLE 1

| | | | | Light | | | |
|---|---|---|---|---|---|---|---|
| | | | | transmittance | | Change in light | |
| | | | | before adding | | transmittance due to | |
| Sample No. | Resin | Additive | Type of Additive | additive (%) | *1 | heat treatment (%) | Remarks |
| Sample 1 | Resin A | none | — | 88 | — | B | Comp. |
| Sample 2 | Resin A | Additive A | Phosphorus- | 86 | 2.2 | A | Inv. |
| | | | containing | | | | |
| | | | compound | | | | |
| Sample 3 | Resin A | Additive B | Phosphorus- | 83 | 5.7 | A | Inv. |
| | | | containing | | | | |
| | | | compound | | | | |
| Sample 4 | Resin A | Additive C | Phenol compound | 74 | 12.2 | B | Comp. |
| Sample 5 | Resin A | Additive D | Sulfur-containing | 88 | 0.3 | B | Comp. |
| | | | compound | | | | |
| Sample 6 | Resin A | Additive E | Hindered amine | 76 | 15.0 | B | Comp. |
| | | | compound | | | | |
| Sample 7 | Resin B | none | — | 82 | — | B | Comp. |
| Sample 8 | Resin B | Additive A | Phosphorus- | 79 | 3.0 | A | Inv. |
| | | | containing | | | | |
| | | | compound | | | | |
| Sample 9 | Resin C | none | — | 89 | — | B | Comp. |
| Sample 10 | Resin C | Additive A | Phosphorus- | 83 | 6.3 | A | Inv. |
| | | | containing | | | | |
| | | | compound | | | | |
| Sample 11 | Resin D | none | — | 85 | — | B | Comp. |
| Sample 12 | Resin D | Additive A | Phosphorus- | 82 | 3.1 | A | Inv. |
| | | | containing | | | | |
| | | | compound | | | | |

*1: Change in light transmittance due to addition of additive (%)
Comp.: Comparative,
Inv.: Inventive

### (3) Conclusions

The results shown in Table 1 clearly shows that the transmittance change before and after the heat treatment was reduced to 10% or less for each of Samples 2, 3, 8, 10 and 12 of the present invention, in each of which an additive was added to the curable resin material, whereby the light transmittance before the heat treatment had been lowered. For Samples 1, 4-7, 9, and 11, no additive had been added to the curable resin material before the heat treatment, whereby the transmittance had not been lowered by 1-10%, or an additive had been added to the curable resin material before the heat treatment to lower the transmittance more than 10%. Samples 1, 4-7, 9, and 11 each had a problem in that the transmittance of each of these samples showed a notable change of transmittance after the heat treatment, which means that the optical property of each of these samples is largely varied before and after the heat treatment. As mentioned above, by adding the additive to the curable resin of the present invention to lower the light transmittance at a wavelength of 400 nm, the decline of the light transmittance after the heat treatment at 260° C. for 3 minutes is reduced by 10% or less. Accordingly, it was found that, even after the practical reflow treatment, the deterioration of the optical property exhibited before heating is only limited and the same level of optical property can be maintained.

1-5. (canceled)

6. An optical element comprising an optical material comprising a curable resin material and at least one additive, the curable resin material comprising a curable resin and a curing agent, wherein
a light transmittance at a wavelength of 400 nm of the optical material is lower by 1-10% than a light transmittance at a wavelength of 400 nm of the curable resin material before addition of the at least one additive.

7. The optical element of claim 5, wherein the additive is a phosphorus-containing stabilizer.

8. The optical element of claim 5, wherein the curable resin is a silicone resin, an epoxy resin, a resin having an adamantane moiety or a resin containing an acrylate.

9. An optical module produced by the steps of:
mounting
the optical element of claim 5, and
at least an electronic circuit and a solder material, on an electronic circuit board;
and heating the electronic circuit board to a temperature at which the solder material is melted.

10. A method of producing an electronic module comprising the steps of:
mounting
the optical element of claim 5, and
at least an electronic circuit and a solder material,
on an electronic circuit board; and
heating the electronic circuit board to a temperature at which the solder material is melted.
